(19) United States
(12) Patent Application Publication
(10) Pub. No.: US 2024/0173751 A1
(43) Pub. Date: May 30, 2024

(54) SUBSTRATE CLEANING CHAMBER, A SUBSTRATE PROCESSING SYSTEM INCLUDING THE SAME, AND A METHOD OF PROCESSING A SUBSTRATE USING THE SUBSTRATE PROCESSING SYSTEM

(71) Applicant: Samsung Electronics Co., Ltd., Suwon-si (KR)

(72) Inventors: SANGJINE PARK, Suwon-si (KR); Ji Hwan PARK, Suwon-si (KR); KUNTACK LEE, Suwon-si (KR)

(21) Appl. No.: 18/336,217

(22) Filed: Jun. 16, 2023

(30) Foreign Application Priority Data
Nov. 30, 2022 (KR) 10-2022-0164886

(51) Int. Cl. B08B 3/02; B08B 3/08; F26B 5/00; G03F 7/38; H01L 21/02

(52) U.S. Cl. CPC B08B 3/022; B08B 3/08; F26B 5/005; G03F 7/38; H01L 21/02057; G03F 7/0042

(57) ABSTRACT

A method of processing a substrate includes wetting a substrate, supplying a supercritical fluid onto the wetted substrate to dry the substrate, and cleaning the dried substrate. The cleaning of the substrate includes supplying a cleaning solution onto a top surface of the substrate, and supplying a cleaning solution onto a bottom surface of the substrate.

### CROSS-REFERENCE TO RELATED APPLICATIONS

This U.S. non-provisional patent application claims priority under 35 U.S.C. § 119 to Korean Patent Application No. 10-2022-0164886, filed on Nov. 30, 2022, in the Korean Intellectual Property Office, the entire contents of which are hereby incorporated by reference.

### BACKGROUND OF THE INVENTION

The present disclosure relates to a substrate cleaning chamber, a substrate processing system including the same and a method of processing a substrate using the substrate processing system, and more particularly, to a substrate cleaning chamber capable of removing a foreign material on a substrate and of preventing contamination, a substrate processing system including the same and a method of processing a substrate using the substrate processing system.

A semiconductor device may be manufactured by various processes. For example, the semiconductor device may be manufactured by a photolithography process, an etching process, a deposition process, and a plating process. In the photolithography process for manufacturing the semiconductor device, a wetting process of applying liquid (e.g., a developing solution) onto a wafer may be performed. In addition, a drying process of removing the liquid, applied on the wafer, from the wafer may be performed. Various methods may be used to apply the liquid onto the wafer and/or to remove the liquid from the wafer.

### SUMMARY

Embodiments of the inventive concepts may provide a substrate cleaning chamber capable of cleaning a substrate coated with a photoresist material including a metal, a substrate processing system including the same, and a method of processing a substrate using the substrate processing system.

Embodiments of the inventive concepts may also provide a substrate cleaning chamber capable of removing a foreign material on a substrate, a substrate processing system including the same, and a method of processing a substrate using the substrate processing system.

Embodiments of the inventive concepts may further provide a substrate cleaning chamber capable of preventing contamination of a substrate, a substrate processing system including the same, and a method of processing a substrate using the substrate processing system.

In an aspect, a method of processing a substrate may include wetting a substrate, supplying a supercritical fluid onto the wetted substrate to dry the substrate, and cleaning the dried substrate. The cleaning of the substrate may include supplying a cleaning solution onto a top surface of the substrate, and supplying a cleaning solution onto a bottom surface of the substrate.

In an aspect, a method of processing a substrate may include wetting a substrate, drying the wetted substrate, cleaning the dried substrate, and heat-treating the cleaned substrate. The wetting of the substrate may include disposing the substrate into a wet chamber, supplying a developing solution onto the substrate disposed in the wet chamber, and supplying a wetting solution onto the substrate after the supplying of the developing solution. The drying of the substrate may include supplying a supercritical fluid onto the substrate supplied with the wetting solution.

In an aspect, a substrate processing system may include a wet chamber, a drying chamber configured to dry a substrate, which has passed through the wet chamber, by using a supercritical fluid, and a substrate cleaning chamber configured to supply a cleaning solution to a substrate which has passed through the drying chamber. The substrate cleaning chamber may include a cleaning chamber housing, an upper cleaning nozzle configured to supply the cleaning solution toward a top surface of a substrate disposed in the cleaning chamber housing, and a lower cleaning nozzle configured to supply the cleaning solution toward a bottom surface of a substrate disposed in the cleaning chamber housing.

In an aspect, a substrate cleaning chamber may include a cleaning chamber housing providing a cleaning space, a support pin located in the cleaning chamber housing and configured to support a substrate, an upper cleaning nozzle located above the support pin, and a lower cleaning nozzle located under a substrate disposed on the support pin.

### BRIEF DESCRIPTION OF THE DRAWINGS

FIG. 1 is a schematic view illustrating a substrate processing system according to some embodiments of the inventive concepts

FIG. 2 is a cross-sectional view illustrating a wet chamber according to some embodiments of the inventive concepts.

FIG. 3 is a cross-sectional view illustrating a drying chamber according to some embodiments of the inventive concepts.

FIG. 4 is a schematic view illustrating a supercritical fluid supply unit according to some embodiments of the inventive concepts.

FIG. 5 is a cross-sectional view illustrating a substrate cleaning chamber according to some embodiments of the inventive concepts.

FIG. 6 is an enlarged cross-sectional view of a region ‘X’ of FIG. 5

FIG. 7 is an enlarged plan view illustrating a portion of a substrate cleaning chamber according to some embodiments of the inventive concepts.

FIG. 8 is a flow chart illustrating a method of processing a substrate according to some embodiments of the inventive concepts

FIGS. 9 to 17 are views illustrating the method of processing a substrate in the flow chart of FIG. 8.

### DETAILED DESCRIPTION

Hereinafter, embodiments of the inventive concepts will be described in detail with reference to the accompanying drawings. The same reference numerals or the same reference designators may denote the same components or elements throughout the specification.

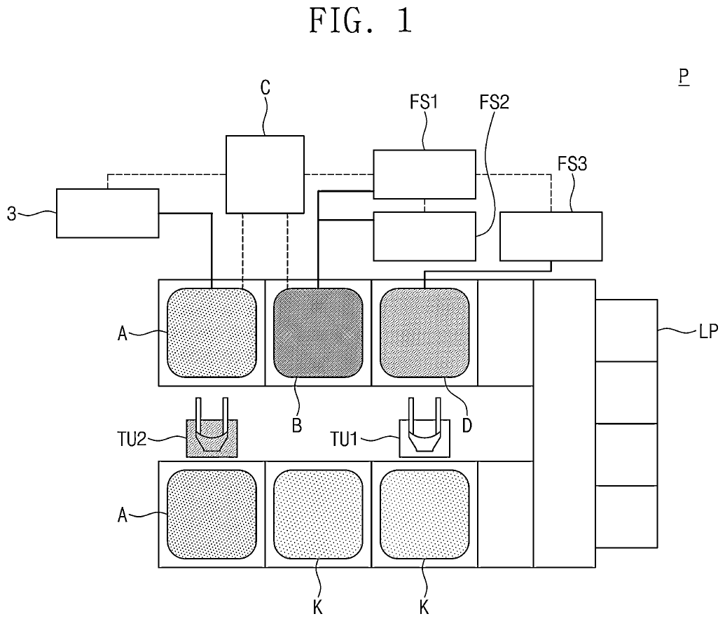

FIG. 1 is a schematic view illustrating a substrate processing system according to some embodiments of the inventive concepts.

Referring to FIG. 1, a substrate processing system P may be provided. The substrate processing system P may be an apparatus for processing a substrate in a semiconductor manufacturing process. More particularly, the substrate processing system P may be an apparatus for performing a wetting process, a drying process and a cleaning process on a substrate. In other words, the substrate processing system P may be configured to wet a substrate by supplying or spraying liquid onto the substrate and/or may be configured to dry and clean the substrate by removing liquid on the substrate from the substrate. For example, the substrate processing system P may be configured to supply or spray a developing solution onto a substrate on which an extreme ultraviolet (EUV) exposure process was performed. In addition, the substrate processing system P may be configured to dry the developing solution on the substrate. The term ‘substrate’ used in the present specification may mean any suitable substrate, such as a semiconductor wafer. The semiconductor wafer may include, but not limited to, a silicon (Si) wafer. The substrate processing system P may include a loading port LP, a wet chamber B, a developing solution supply unit FS1, a wetting solution supply unit FS2, a first transfer unit TU1, a second transfer unit TU2, a drying chamber A, a substrate cleaning chamber D, a cleaning solution supply unit FS3, a bake chamber K, a supercritical fluid supply unit 3, and a control unit C

The loading port LP may be a port on which a substrate is loaded. For example, a substrate on which various semiconductor manufacturing processes were performed may be loaded on the loading port LP. A plurality of loading ports LP may be provided. A plurality of substrates may be loaded on each of the plurality of loading ports LP. However, a single loading port LP will be mainly described hereinafter for ease of explanation.

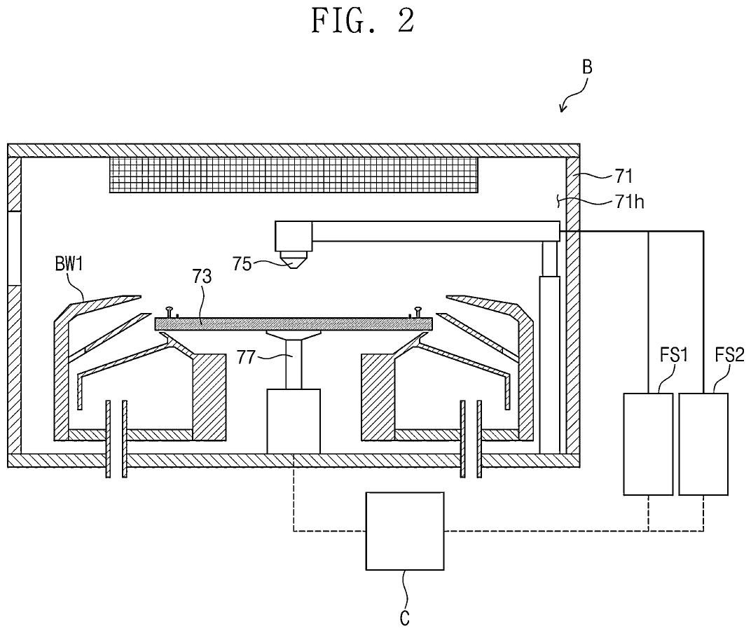

The wet chamber B may be a chamber for performing a wetting process on a substrate. The wet chamber B may provide a space in which the wetting process is performed. When a substrate is disposed in the wet chamber B, liquid such as various chemicals and/or water may be coated onto the substrate. The coating of the liquid may be performed by various methods. For example, the liquid may be supplied or sprayed onto a rotating substrate, and thus the liquid may be uniformly distributed on the substrate by centrifugal force. The wet chamber B will be described later in more detail with reference to FIG. 2.

The developing solution supply unit FS1 may be configured to supply a fluid into the wet chamber B. To achieve this, the developing solution supply unit FS1 may include a fluid tank and a pump. The fluid supplied into the wet chamber B by the developing solution supply unit FS1 may be referred to as a developing solution. The developing solution may include various chemicals and/or water. More particularly, the developing solution may include propylene glycol methyl ether acetate (PGMEA) and acetic acid. Depending upon the photoresist, alternatives or additions to PGMEA could be used such as PGME, 2-butanone, 2-heptanone, 2-butanol, 2-heptanol, ethyl acetate, cyclohexyl acetate, methyl laurate, diisobutyl ketone, 4-methyl-2-pentanol, or dibutyl oxalate. A carboxylic acid such as acetic acid mentioned above can be used, or other carboxylic acids such as formic acid, oxalic acid or 2-ethylhexanoic acid could be used, and in addition or in place of the carboxylic acid, other polar solvents such as diols, glycol ethers, monohydroxyl alcohols, polyhydroxyl compounds, glycol ethers and/or pyrrolidones could be used, depending upon the photoresist. If acetic acid is used, a concentration of the acetic acid in the developing solution may range from about 1 wt % to about 3 wt %, but embodiments of the inventive concepts are not limited thereto. This will be described later in more detail.

The wetting solution supply unit FS2 may be configured to supply a fluid into the wet chamber B. To achieve this, the wetting solution supply unit FS2 may include a fluid tank and a pump. The fluid supplied into the wet chamber B by the wetting solution supply unit FS2 may be referred to as a wetting solution. The wetting solution may include various chemicals and/or water. More particularly, the wetting solution may include propylene glycol methyl ether acetate (PGMEA). This will be described later in more detail.

The first transfer unit TU1 may be configured to transfer a substrate not contaminated by a foreign material. For example, the first transfer unit TU1 may transfer a substrate loaded on the loading port LP into the wet chamber B. In addition, the first transfer unit TU1 may take a substrate out of the substrate cleaning chamber D and then may transfer the substrate into the bake chamber K. To achieve this, the first transfer unit TU1 may include an actuator (e.g., a motor).

The second transfer unit TU2 may be distinguished from the first transfer unit TU1. The second transfer unit TU2 may be configured to transfer a substrate contaminated by a foreign material. For example, the second transfer unit TU2 may take a substrate out of the wet chamber B and then may transfer the substrate into the drying chamber A. In addition, the second transfer unit TU2 may take a substrate out of the drying chamber A and then may transfer the substrate into the substrate cleaning chamber D. To achieve this, the second transfer unit TU2 may include an actuator (e.g., a motor).

The drying chamber A may be a chamber for drying a substrate. For example, the drying chamber A may be configured to dry and/or clean a substrate which has passed through the wet chamber B. In other words, the drying chamber A may remove liquid from a substrate coated with the developing solution and/or the wetting solution in the wet chamber B. The drying chamber A may provide a space in which the drying process is performed. The drying chamber A may be provided in plurality. For example, two drying chambers A may be provided. The two drying chambers A may be provided to face each other. However, hereinafter, a single drying chamber A will be mainly described for the purpose of ease and convenience in explanation.

The substrate cleaning chamber D may be configured to clean a substrate. More particularly, the substrate cleaning chamber D may clean a substrate which has passed through the drying chamber A. The substrate cleaning chamber D may be configured to supply or spray a cleaning solution on a substrate. This will be described later in more detail.

The cleaning solution supply unit FS3 may be configured to supply the cleaning solution into the substrate cleaning chamber D. To achieve this, the cleaning solution supply unit FS3 may include a fluid tank and a pump. The cleaning solution may include various chemicals and/or water. More particularly, the cleaning solution may include propylene glycol methyl ether acetate (PGMEA) and acetic acid. A concentration of the acetic acid of the cleaning solution may range from about 20 wt % to about 50 wt %, but embodiments of the inventive concepts are not limited thereto. This will be described later in more detail.

The bake chamber K may be configured to heat-treat a substrate. More particularly, the bake chamber K may heat-treat a substrate which has passed through the substrate cleaning chamber D. The heat treatment process by the bake chamber K may be referred to as a bake process.

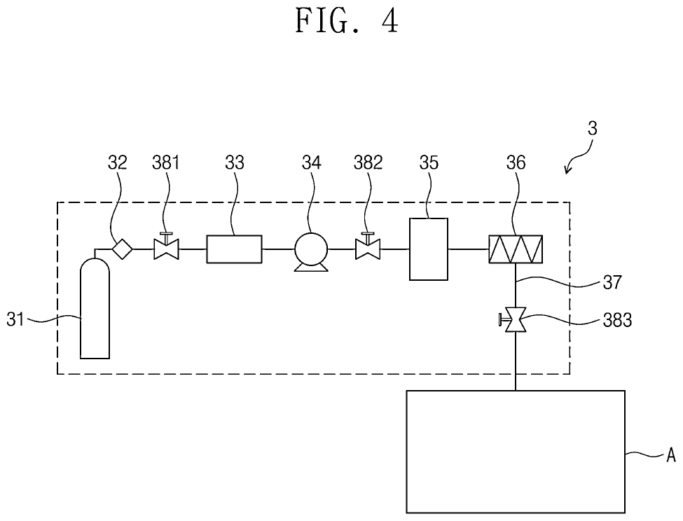

The supercritical fluid supply unit 3 may be configured to supply a fluid into the drying chamber A. More particularly, the supercritical fluid supply unit 3 may be configured to supply a supercritical fluid supplied or injected into the drying chamber A. For example, the supercritical fluid supply unit 3 may supply carbon dioxide (CO₂) in a supercritical fluid (SCF) state into the drying chamber A. The supply unit 3 may also be configured to supply near critical fluids, as well as supercritical or near critical fluids other than CO₂ such as H₂O or alcohols such as methanol or ethanol, or combinations such as methanol modified supercritical CO₂, ethanol modified supercritical CO₂, etc. The supercritical fluid supply unit 3 will be described later in more detail with reference to FIG. 4.

The control unit C may control the wet chamber B and the drying chamber A. For example, the control unit C may control the supercritical fluid supply unit 3 to adjust the degree of drying of a substrate. More particularly, the control unit C may control the flow rate of a fluid supplied into the drying chamber A.

FIG. 2 is a cross-sectional view illustrating a wet chamber according to some embodiments of the inventive concepts.

Referring to FIG. 2, the wet chamber B may include a wet chamber housing 71, a wetting stage 73, a wetting nozzle 75, a rotation shaft 77, and a first bowl BW1.

The wet chamber housing 71 may provide a wetting space 71h. The wetting process may be performed on a substrate in a state in which the substrate is disposed in the wetting space 71h.

The wetting stage 73 may be located in the wet chamber housing 71. The wetting stage 73 may be configured to support a substrate. In other words, a substrate inserted in the wet chamber housing 71 may be disposed on the wetting stage 73. The wetting stage 73 may be configured to rotate a substrate.

The wetting nozzle 75 may be spaced upward from the wetting stage 73. The wetting nozzle 75 may be connected to the developing solution supply unit FS1 and the wetting solution supply unit FS2. The wetting nozzle 75 may be supplied with the fluid from each of the developing solution supply unit FS1 and the wetting solution supply unit FS2 and may supply or spray the fluid toward the wetting stage 73.

The rotation shaft 77 may be configured to rotate the wetting stage 73 in response to a control signal of the control unit C. A substrate on the wetting stage 73 may be rotated by the rotation shaft 77.

The first bowl BW1 may surround the wetting stage 73. The first bowl BW1 may collect a fluid escaping or scattered from the wetting stage 73.

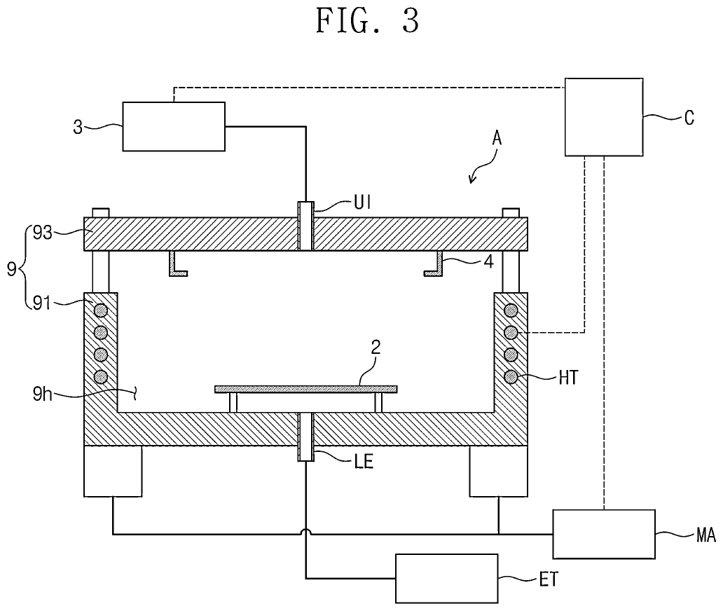

FIG. 3 is a cross-sectional view illustrating a drying chamber according to some embodiments of the inventive concepts.

Referring to FIG. 3, the drying chamber A may be configured to dry a substrate. More particularly, liquid on a substrate may be removed from the substrate in the drying chamber A. A substrate wetted in the wet chamber B (see FIG. 2) may be dried in the drying chamber A. The drying chamber A may include a drying chamber housing 9, a drying heater HT, a drying chuck 4, a blocking plate 2, a chamber driving unit MA, and an exhaust tank ET.

The drying chamber housing 9 may provide a drying space 9h. The drying chamber housing 9 may include a lower housing 91 and an upper housing 93. The lower housing 91 may be spaced downward from the upper chamber 93. The drying space 9h may be provided between the lower housing 91 and the upper housing 93. The lower housing 91 may be vertically movable. For example, the lower housing 91 may be moved upward by the chamber driving unit MA and thus may be coupled to the upper housing 93. The lower housing 91 and the upper housing 93 may be coupled to each other to isolate the drying space 9h from the outside. An upper inlet UI may be provided at the upper housing 93. The upper inlet UI may be connected to the supercritical fluid supply unit 3. The supercritical fluid may be supplied from the supercritical fluid supply unit 3 into the drying space 9h through the upper inlet UI. A lower outlet LE may be provided at the lower housing 91. The lower outlet LE may be connected to the exhaust tank ET. A fluid may be exhausted to the outside of the drying chamber housing 9 through the lower outlet LE.

The drying heater HT may be coupled to the drying chamber housing 9. The drying heater HT may be configured to heat the drying space 9h. The supercritical fluid supplied in the drying space 9h may be maintained in a supercritical state by heating of the drying heater HT.

The drying chuck 4 may be connected to the upper housing 93. The drying chuck 4 may be spaced downward from the upper housing 93. A substrate may be disposed or placed on the drying chuck 4. In other words, the drying chuck 4 may support the substrate.

The blocking plate 2 may be connected to the lower housing 91. The blocking plate 2 may be spaced upward from the lower outlet LE by a certain distance. The blocking plate 2 may block the flowing of a fluid. The chamber driving unit MA may be connected to the lower housing 91. The chamber driving unit MA may be configured to vertically move the lower housing 91. By the chamber driving unit MA, the lower housing 91 may be coupled to the upper housing 93 or may be separated from the upper housing 93. To achieve this, the chamber driving unit MA may include an actuator (e.g., a motor). The exhaust tank ET may be connected to the lower outlet LE. The fluid exhausted through the lower outlet LE may move to the exhaust tank ET.

FIG. 4 is a schematic view illustrating a supercritical fluid supply unit according to some embodiments of the inventive concepts.

Referring to FIG. 4, the supercritical fluid supply unit 3 may include a drying fluid supply source 31, a drying fluid line 37, a supply filter 32, a first valve 381, a condenser 33, a pump 34, a second valve 382, a tank 35, a heater 36, and a third valve 383.

The drying fluid supply source 31 may be configured to supply a drying fluid. More particularly, the drying fluid supply source 31 may store and supply a gaseous fluid to be formed into the supercritical fluid. In the case in which the drying fluid is a CO₂ supercritical fluid, the drying fluid supply source 31 may store gaseous CO₂. A temperature of the gaseous CO₂ supplied by the drying fluid supply source 31 may range from about 10° C. to about 30° C. In addition, a pressure of the gaseous CO₂ supplied by the drying fluid supply source 31 may range from about 4 MPa to about 6 MPa. The drying fluid supplied from the drying fluid supply source 31 may move along the drying fluid line 37.

The drying fluid line 37 may provide a path for supplying the drying fluid from the drying fluid supply source 31 into the drying chamber A. The supply filter 32 may be located on the drying fluid line 37. The supply filter 32 may filter a foreign material in the drying fluid. The first valve 381 may open/close a flow path between the supply filter 32 and the condenser 33 to control movement of the drying fluid.

The condenser 33 may cool the gaseous CO₂ supplied from the drying fluid supply source 31. Thus, the gaseous CO₂ may be liquefied in the condenser 33. For example, a temperature of the CO₂ liquefied in the condenser 33 may range from about 0° C. to about 6° C. In addition, a pressure of the CO₂ liquefied in the condenser 33 may range from about 4 MPa to about 6 MPa.

The pump 34 may be configured to increase the pressure of the drying fluid liquefied through the condenser 33. For example, the pressure of the CO₂ liquefied in the condenser 33 may become in a range of about 15 MPa to about 25 MPa by the pump 34. In addition, the temperature of the CO₂ liquefied in the condenser 33 may become in a range of about 15° C. to about 25° C. while passing through the pump 34. The second valve 382 may open/close a flow path between the pump 34 and the tank 35 to control movement of the drying fluid. The tank 35 may store the drying fluid compressed by the pump 34.

The heater 36 may be configured to heat the drying fluid moving along the drying fluid line 37. More particularly, the heater 36 may heat the CO₂ in a liquid state, which is compressed by the pump 34. Thus, the CO₂ in the liquid state may become in a supercritical state. The CO₂ in the supercritical state, which is formed by the heating of the heater 36, may be in a high-temperature and high-pressure state. For example, a temperature of the CO₂ in the supercritical state through the heater 36 may range from about 60° C. to about 90° C. In addition, a pressure of the CO₂ in the supercritical state through the heater 36 may range from about 15 MPa to about 25 MPa. The third valve 383 may control movement of the CO₂ in the supercritical state through the heater 36. The CO₂ in the supercritical state may be supplied or injected into the drying chamber A through the third valve 383.

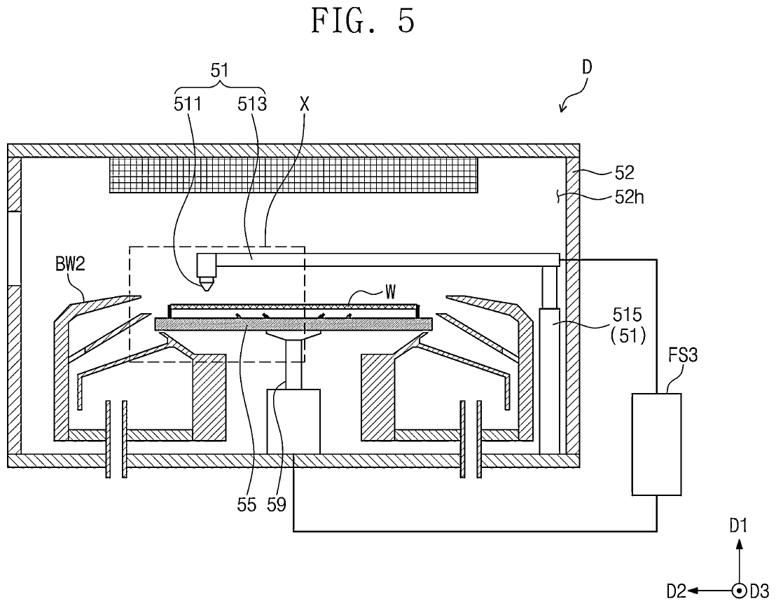

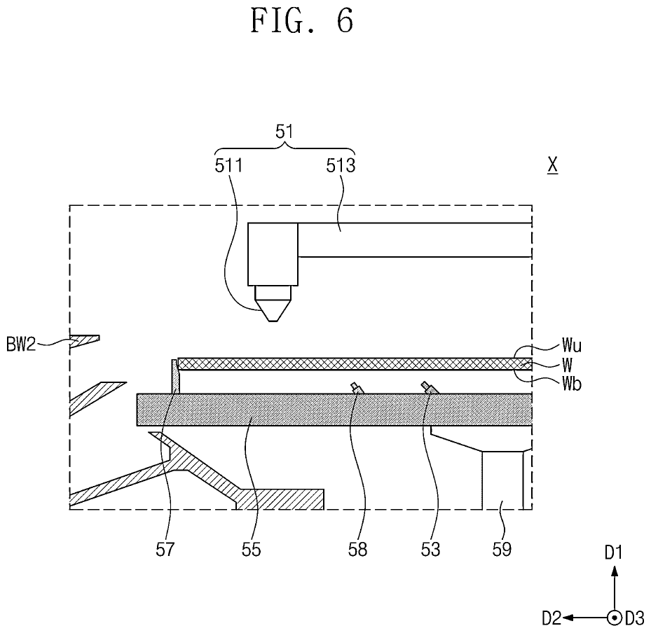

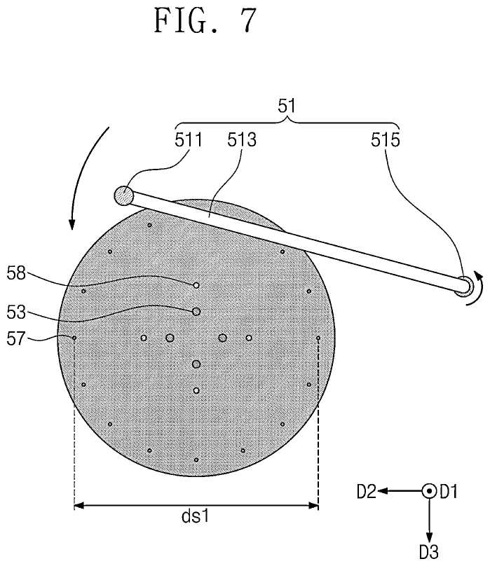

FIG. 5 is a cross-sectional view illustrating a substrate cleaning chamber according to some embodiments of the inventive concepts, FIG. 6 is an enlarged cross-sectional view of a region ‘X’ of FIG. 5, and FIG. 7 is an enlarged plan view illustrating a portion of a substrate cleaning chamber according to some embodiments of the inventive concepts.

Referring to FIGS. 5 to 7, the substrate cleaning chamber D may include a cleaning chamber housing 52, a cleaning stage 55, a substrate rotation unit 59, a support pin 57, a cleaning unit 51, a lower cleaning nozzle 53, a gas nozzle 58, and a second bowl BW2.

The cleaning chamber housing 52 may provide a cleaning space 52h. A cleaning process may be performed on a substrate in the cleaning space 52h. More particularly, a process of removing a foreign material (e.g., a metal, etc.) on a substrate may be performed in the cleaning space 52h.

The cleaning stage 55 may be located in the cleaning chamber housing 52. The cleaning stage 55 may have a circular plate shape as shown in FIG. 7, but embodiments of the inventive concepts are not limited thereto. The cleaning stage 55 may be configured to be rotated by the substrate rotation unit 59

The substrate rotation unit 59 may support the cleaning stage 55. The substrate rotation unit 59 may extend in a first direction D1. The substrate rotation unit 59 may be configured to rotate the cleaning stage 55.

The support pin 57 may be located on the cleaning stage 55. The support pin 57 may be provided in plurality. As shown in FIG. 7, the plurality of support pins 57 may be arranged in a circumferential direction. A distance ds1 between two support pins, farthest from each other, of the plurality of support pins 57 may be about 290 mm or more. More particularly, the distance ds1 between the two support pins, farthest from each other, of the plurality of support pins 57 may be about 295 mm or more. Hereinafter, a single support pin 57 will be mainly described for the purpose of ease and convenience in explanation.

The cleaning unit 51 may be configured to supply or spray a cleaning solution toward the cleaning stage 55. The cleaning unit 51 may be connected to the cleaning solution supply unit FS3. The cleaning unit 51 may include an upper cleaning nozzle 511, a nozzle connection member 513, and an upper nozzle moving unit 515

The upper cleaning nozzle 511 may be located above the support pin 57. The upper cleaning nozzle 511 may supply or spray the cleaning solution toward a substrate W disposed on the cleaning stage 55. More particularly, the upper cleaning nozzle 511 may supply or spray the cleaning solution toward a top surface Wu of the substrate W.

The nozzle connection member 513 may support the upper cleaning nozzle 511. The nozzle connection member 513 may extend in a horizontal direction. The cleaning solution supplied from the cleaning solution supply unit FS3 may move along the nozzle connection member 513 and then may be supplied or sprayed through the upper cleaning nozzle 511.

The upper nozzle moving unit 515 may be configured to move the nozzle connection member 513 and/or the upper cleaning nozzle 511. For example, the upper nozzle moving unit 515 may move the upper cleaning nozzle 511 in a horizontal direction on the cleaning stage 55. More particularly, the upper nozzle moving unit 515 may rotate the nozzle connection member 513 to move the upper cleaning nozzle 511 in the horizontal direction on the cleaning stage 55. To achieve this, the upper nozzle moving unit 515 may include an actuator (e.g., a motor).

The lower cleaning nozzle 53 may be located under the substrate W disposed on the support pin 57. The lower cleaning nozzle 53 may be connected to the cleaning solution supply unit FS3. The lower cleaning nozzle 53 may supply or spray the cleaning solution toward the substrate W. More particularly, the lower cleaning nozzle 53 may supply or spray the cleaning solution toward a bottom surface Wb of the substrate W. The lower cleaning nozzle 53 may be provided in plurality. The plurality of lower cleaning nozzles 53 may be arranged in the circumferential direction as shown in FIG. 7. Hereinafter, a single lower cleaning nozzle 53 will be mainly described for the purpose of ease and convenience in explanation.

The gas nozzle 58 may be located under the substrate W disposed on the support pin 57. The gas nozzle 58 may supply or jet a gas toward the substrate W. More particularly, the gas nozzle 58 may supply or jet the gas toward the bottom surface Wb of the substrate W.

The gas nozzle 58 may be located outside the lower cleaning nozzle 53. The gas nozzle 58 may be provided in plurality. The plurality of gas nozzles 58 may be arranged in the circumferential direction as shown in FIG. 7. Hereinafter, a single gas nozzle 58 will be mainly described for the purpose of ease and convenience in explanation.

The second bowl BW2 may surround the cleaning stage 55. The second bowl BW2 may collect a fluid escaping or scattered from the cleaning stage 55.

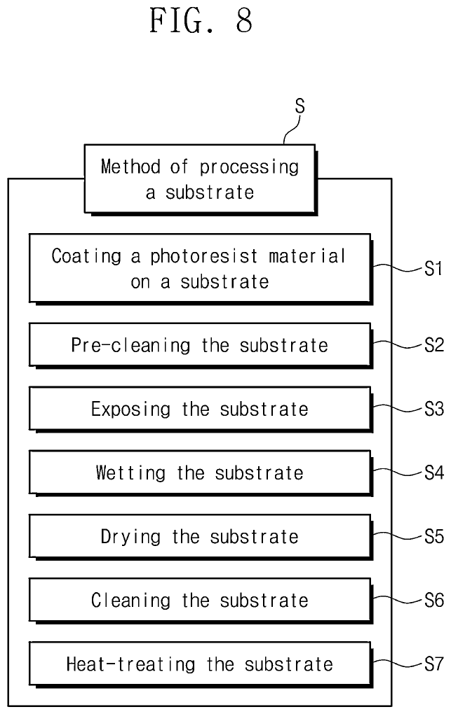

FIG. 8 is a flow chart illustrating a method of processing a substrate according to some embodiments of the inventive concepts.

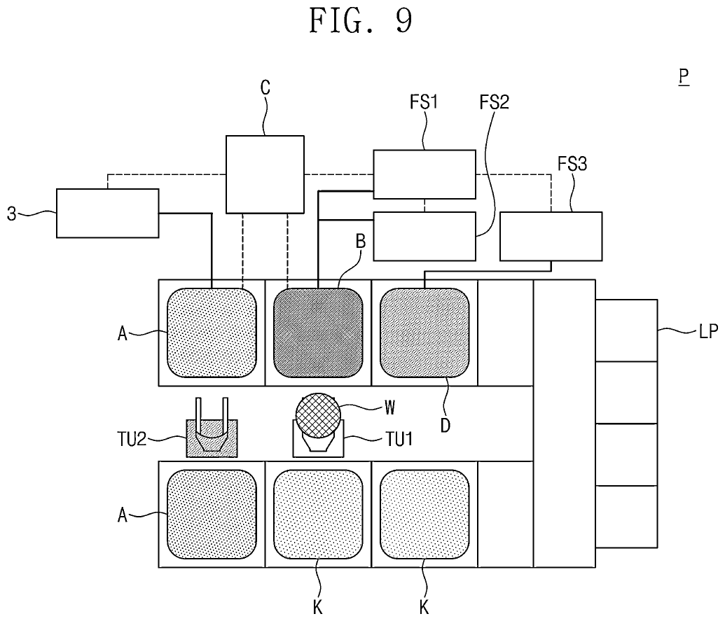

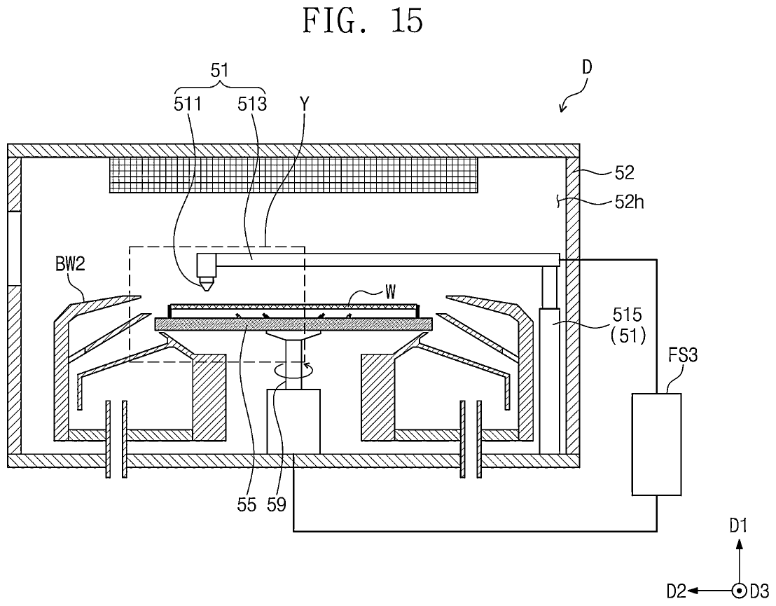

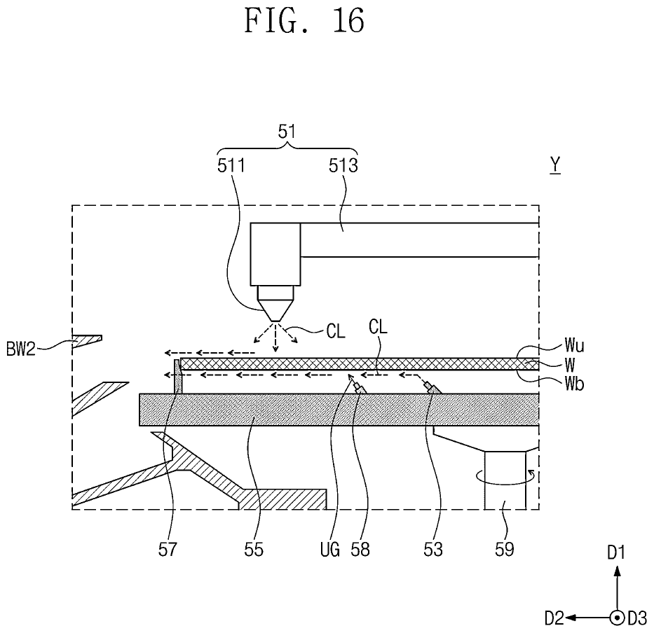

Referring to FIG. 8, a method of processing a substrate (S) may be provided. The method of processing a substrate (S) may be a method of processing a substrate using the substrate processing system P (see FIG. 1) described with reference to FIGS. 1 to 7. The method of processing a substrate (S) may include coating a photoresist material on a substrate (S1), pre-cleaning the substrate (S2), exposing the substrate (S3), wetting the substrate (S4), drying the substrate (S5), cleaning the substrate (S6), and heat-treating the substrate (S7). Hereinafter, the method of processing a substrate (S) in FIG. 8 will be described in more detail with reference to FIGS. 9 to 17.

FIGS. 9 to 17 are views illustrating the method of processing a substrate in the flow chart of FIG. 8.

Referring to FIG. 8, the coating of the photoresist material on the substrate (S1) may include coating the photoresist material including a metal on the substrate. The metal can be a metal oxide nanoparticle or metal organic cluster/metal oxide ligand cluster in the deposited photoresist material, where the metal can be e.g., Hf, Zr, Ti, Sn, Zn or In. The photoresist material may be coated on the substrate by at least one of various methods. For example, the photoresist material may be supplied (e.g., dip coated, spin coated, spray coated, etc.) onto a stationary or rotating substrate, so as to provide the photoresist material uniformly coated on the substrate. The pre-cleaning of the substrate (S2) may include cleaning the substrate coated with the photoresist material. The exposing of the substrate (S3) may include exposing the substrate coated with the photoresist material.

Referring to FIGS. 9, 10 and 8, the wetting of the substrate (S4) may include disposing or placing a substrate W in the wet chamber B by the first transfer unit TU1. In this process, the substrate W may have the photoresist material coated thereon. The substrate W may be disposed on the wetting stage 73.

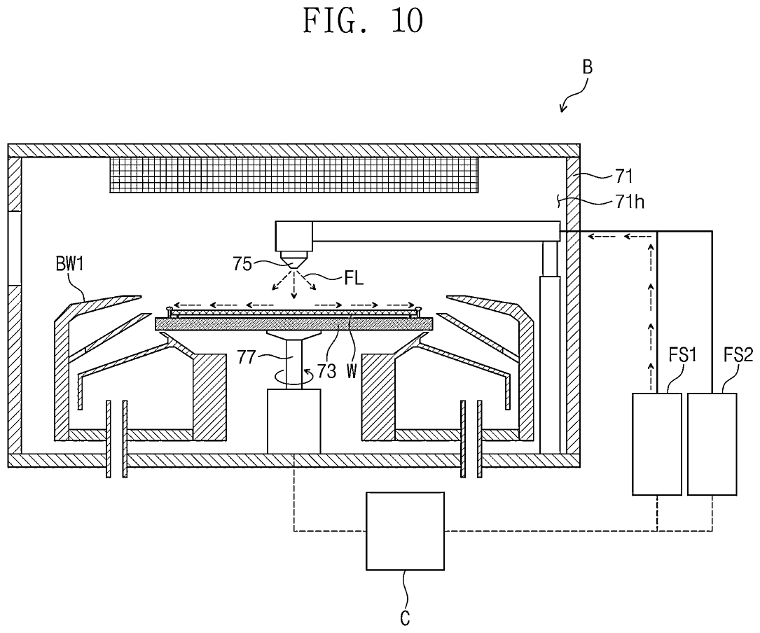

Referring to FIGS. 10 and 8, the wetting of the substrate (S4) may include supplying or spraying a developing solution FL onto the substrate W disposed in the wet chamber B. The developing solution FL supplied from the developing solution supply unit FS1 may be supplied or sprayed onto the substrate W through the wetting nozzle 75. The developing solution FL may include propylene glycol methyl ether acetate (PGMEA) and acetic acid as described above, but embodiments of the inventive concepts are not limited thereto. In this process, the substrate W may be rotated. In other words, the wetting stage 73 may be rotated by the rotation shaft 77 to rotate the substrate W. Thus, the developing solution FL supplied on the substrate W may be spread on a top surface of the substrate W.

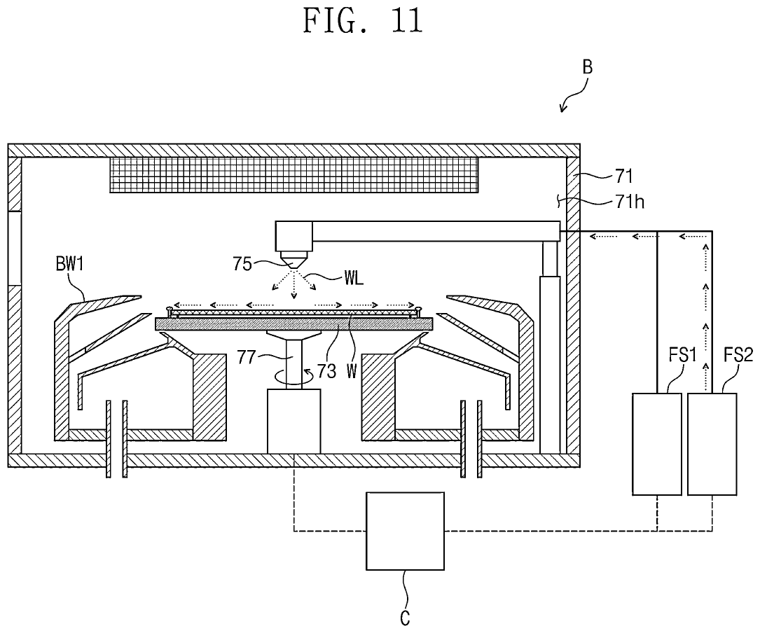

Referring to FIGS. 11 and 8, the wetting of the substrate (S4) may further include supplying or spraying a wetting solution WL onto the substrate W disposed in the wet chamber B. The supplying of the wetting solution WL may be performed after the supplying of the developing solution FL is completed.

The wetting solution WL supplied from the wetting solution supply unit FS2 may be supplied or sprayed onto the substrate W through the wetting nozzle 75. The wetting solution WL may be distinguished from the developing solution FL. In other words, the wetting solution WL and the developing solution FL may be different materials. For example, the wetting solution WL may include propylene glycol methyl ether acetate (PGMEA) as described above, but embodiments of the inventive concepts are not limited thereto. In this process, the substrate W may be rotated. In other words, the wetting stage 73 may be rotated by the rotation shaft 77 to rotate the substrate W. Thus, the wetting solution WL supplied on the substrate W may be spread on the top surface of the substrate W.

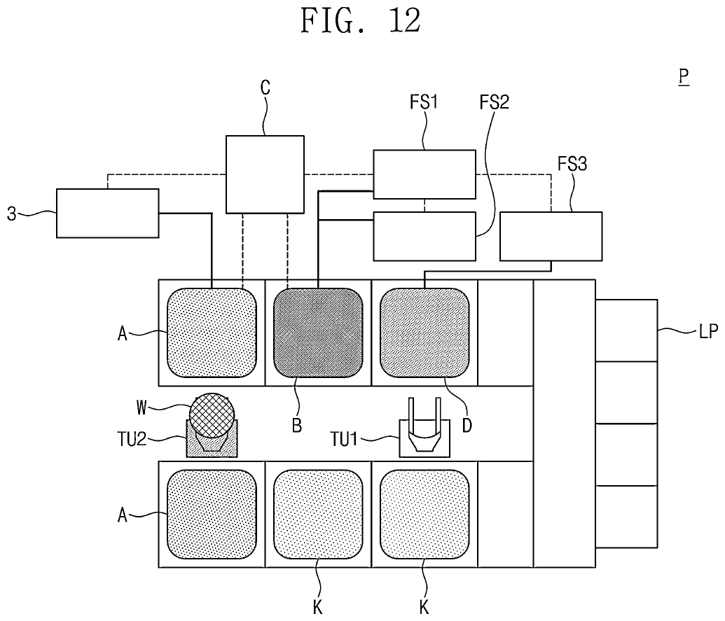

Referring to FIGS. 12 and 8, the drying of the substrate (S5) may include transferring the substrate W into the drying chamber A by the second transfer unit TU2. In this process, the substrate W may have the wetting solution coated thereon. In addition, metal particles may remain on the substrate W.

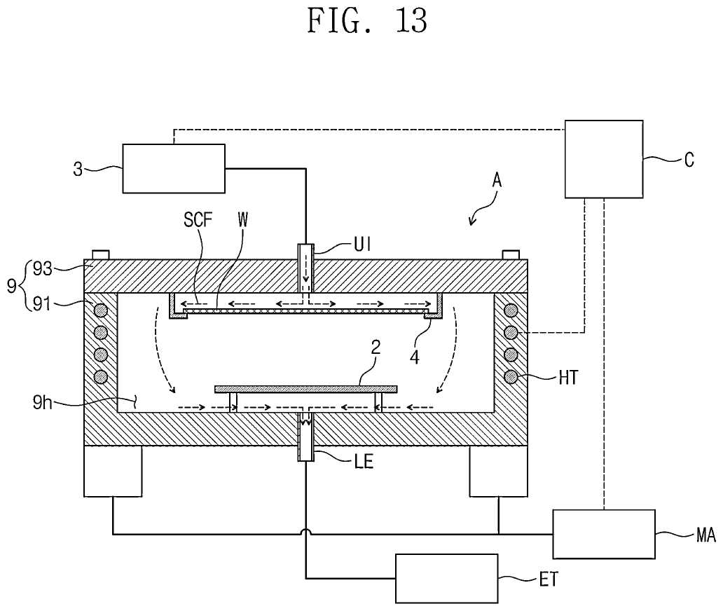

Referring to FIGS. 13 and 8, the drying of the substrate (S5) may include supplying a supercritical fluid SCF onto the substrate W. The supercritical fluid SCF supplied from the supercritical fluid supply unit 3 may be supplied or sprayed onto the substrate W disposed on the drying chuck 4. The wetting solution coated on the substrate W may be removed from the substrate W by the supercritical fluid SCF. In this process, some of the metal particles existing on the substrate W may be removed from the substrate W. However, the others of the metal particles existing on the substrate W may continuously remain on the substrate W.

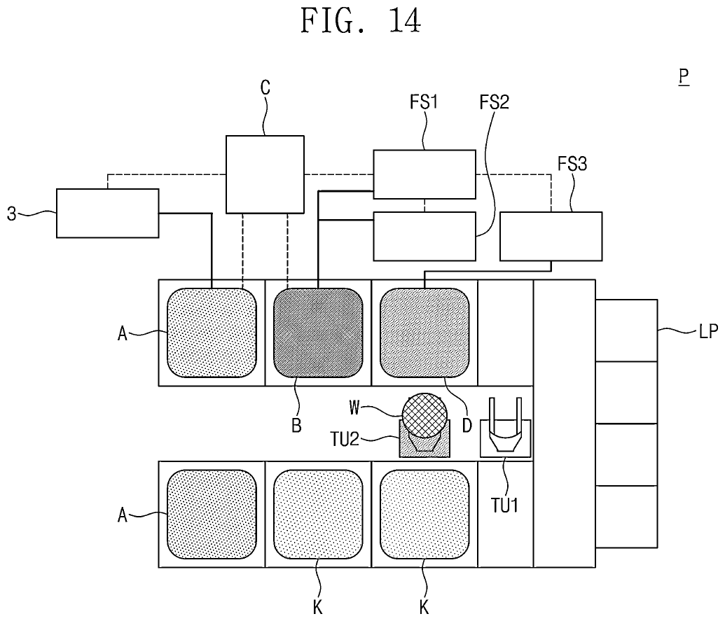

Referring to FIGS. 14 and 8, the cleaning of the substrate (S6) may include transferring the substrate W into the substrate cleaning chamber D by the second transfer unit TU2. In this process, some of the metal particles may remain on the substrate W.

Referring to FIGS. 15, 16 and 8, the cleaning of the substrate (S6) may include disposing or placing the substrate W on the support pin 57. The substrate W may be supported by the support pin 57. The substrate W disposed on the support pin 57 may be spaced upward from the cleaning stage 55. Thus, a bottom surface Wb of the substrate W may be exposed.

The cleaning of the substrate (S6) may include supplying or spraying a cleaning solution CL onto a top surface Wu of the substrate W. The upper cleaning nozzle 511 may be disposed on an edge region of the substrate W. The upper cleaning nozzle 511 may supply or spray the cleaning solution CL onto the edge region of the substrate W. In this process, the substrate W may be rotated. Thus, the cleaning solution CL supplied on the top surface Wu of the substrate W may escape outside the substrate W. As a result, the metal particles remaining on the edge region of the top surface Wu of the substrate W may be removed.

The cleaning of the substrate (S6) may include supplying or spraying the cleaning solution CL onto the bottom surface Wb of the substrate W. The lower cleaning nozzle 53 may supply or spray the cleaning solution CL onto the bottom surface Wb of the substrate W.

In this process, the substrate W may be rotated. Thus, the cleaning solution CL supplied on the bottom surface Wb of the substrate W may escape outside the substrate W. As a result, the metal particles remaining on the bottom surface Wb of the substrate W may be removed.

In some embodiments, a gas UG may be supplied or jetted onto the bottom surface Wb of the substrate W. More particularly, the gas UG may be supplied or jetted onto the bottom surface Wb of the substrate W through the gas nozzle 58. Thus, the cleaning solution CL supplied on the bottom surface Wb of the substrate W may not drop downward but may laterally move outside the substrate W.

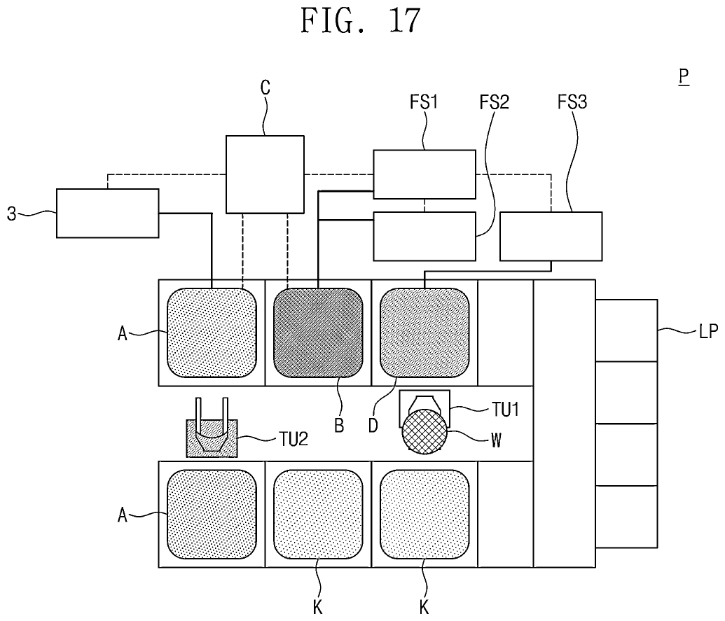

Referring to FIGS. 17 and 8, the heat-treating of the substrate (S7) may include transferring the substrate W into the bake chamber K by the first transfer unit TU1. In this process, a metal material may not exist on the substrate W. In other words, the metal on the substrate W may be removed in the substrate cleaning chamber D, and thus a foreign material (e.g., the metal, etc.) may not exist on the substrate W. The bake chamber K may heat the substrate W.

According to the substrate cleaning chamber, the substrate processing system including the same and the method of processing a substrate using the same in the embodiments of the inventive concepts, the substrate coated with the photoresist material including the metal may be cleaned. Even though the drying process using the supercritical fluid is performed, the photoresist material including the metal may not be removed from the substrate. Thus, after the drying process using the supercritical fluid, the cleaning solution may be supplied in the substrate cleaning chamber to remove the metal particles remaining on the substrate, from the substrate.

According to the substrate cleaning chamber, the substrate processing system including the same and the method of processing a substrate using the same in the embodiments of the inventive concepts, a foreign material existing on the edge region, a side surface and/or the bottom surface of the substrate may be removed from the substrate. In other words, the cleaning solution may be supplied to the top surface and the bottom surface of the substrate to clean the substrate.

According to the substrate cleaning chamber, the substrate processing system including the same and the method of processing a substrate using the same in the embodiments of the inventive concepts, the developing solution including the acetic acid may be supplied onto the substrate in the wet chamber. Thus, the developing process may be smoothly performed on the substrate coated with the photoresist material including the metal.

According to the substrate cleaning chamber, the substrate processing system including the same and the method of processing a substrate using the same in the embodiments of the inventive concepts, the wetting solution may be additionally supplied onto the substrate in the wet chamber after the supplying of the developing solution. The wetting solution may be a fluid of which a kind is different from that of the developing solution. For example, the wetting solution may include a fluid having excellent substitution with the supercritical fluid. Thus, the drying process using the supercritical fluid may be smoothly performed.

According to the substrate cleaning chamber, the substrate processing system including the same and the method of processing a substrate using the same in the embodiments of the inventive concepts, it is possible to prevent a substrate from being contaminated by a transfer unit. More particularly, the substrate processing system may have the transfer unit for transferring a substrate in a section in which a contaminated substrate is moved and the transfer unit for transferring a substrate in a section in which a cleaned substrate is moved, which are different from each other. Thus, it is possible to prevent a cleaned substrate from being contaminated by metal particles stuck on a transfer unit while the cleaned substrate is transferred by the transfer unit which has transferred a substrate contaminated by the metal particles.

According to the substrate cleaning chamber, the substrate processing system including the same and the method of processing a substrate using the same in the inventive concepts, the substrate coated with the photoresist material including the metal may be cleaned.

According to the substrate cleaning chamber, the substrate processing system including the same and the method of processing a substrate using the same in the inventive concepts, a foreign material on the substrate may be removed.

According to the substrate cleaning chamber, the substrate processing system including the same and the method of processing a substrate using the same in the inventive concepts, contamination of the substrate may be prevented.

While the embodiments of the inventive concepts have been particularly shown and described, it will be understood by one of ordinary skill in the art that variations in form and detail may be made therein without departing from the spirit and scope of the attached claims.

1. A method of processing a substrate, the method comprising:
wetting a substrate;
supplying a supercritical fluid onto the wetted substrate to dry the substrate; and
cleaning the dried substrate,
wherein the cleaning of the substrate comprises:
supplying a cleaning solution onto a top surface of the substrate; and
supplying a cleaning solution onto a bottom surface of the substrate.

2. The method of claim 1, wherein the cleaning solution supplied onto the top surface of the substrate includes propylene glycol methyl ether acetate (PGMEA) and acetic acid.

3. The method of claim 2, wherein a concentration of the acetic acid of the cleaning solution supplied onto the top surface of the substrate ranges from 20 wt % to 50 wt %.

4. The method of claim 1, wherein the wetting of the substrate comprises:
supplying a developing solution onto the substrate disposed in a wet chamber; and
supplying a wetting solution different from the developing solution onto the substrate after the supplying of the developing solution.

5. The method of claim 1, wherein the supplying of the cleaning solution onto the top surface of the substrate comprises: supplying the cleaning solution onto an edge region of the top surface through an upper cleaning nozzle located above the top surface.

6. The method of claim 1, wherein the cleaning of the substrate comprises: rotating the substrate.

7. The method of claim 1, further comprising:
coating a photoresist material on the substrate before the wetting of the substrate; and
exposing the substrate coated with the photoresist material,
wherein the photoresist material includes a metal.

8. The method of claim 7, further comprising:
pre-cleaning the substrate after the coating of the photoresist material on the substrate and before the exposing of the substrate.

9. A method of processing a substrate, the method comprising:
wetting a substrate,
drying the wetted substrate;
cleaning the dried substrate; and
heat-treating the cleaned substrate,
wherein the wetting of the substrate comprises:
disposing the substrate into a wet chamber,
supplying a developing solution onto the substrate disposed in the wet chamber; and
supplying a wetting solution onto the substrate after the supplying of the developing solution,
wherein the drying of the substrate comprises: supplying a supercritical fluid onto the substrate supplied with the wetting solution.

10. The method of claim 9, wherein the developing solution includes propylene glycol methyl ether acetate (PGMEA) and acetic acid, and
wherein the wetting solution includes PGMEA.

11. The method of claim 10, wherein a concentration of the acetic acid of the developing solution ranges from 1 wt % to 3 wt %.

12. The method of claim 9, wherein the cleaning of the dried substrate comprises: supplying a cleaning solution onto the substrate,
wherein the cleaning solution supplied onto the substrate includes PGMEA and acetic acid, and
wherein a concentration of the acetic acid of the cleaning solution supplied onto the substrate ranges from 20 wt % to 50 wt %.

13. The method of claim 12, wherein the supplying of the cleaning solution onto the substrate comprises:
supplying the cleaning solution onto a top surface of the substrate; and
supplying the cleaning solution onto a bottom surface of the substrate.

14. The method of claim 9, wherein the drying of the substrate comprises:
transferring the substrate into a drying chamber by a first transfer unit, and
wherein the heat-treating of the substrate comprises: transferring the substrate into a bake chamber by a second transfer unit different from the first transfer unit.

15. A substrate processing system comprising:
a wet chamber;
a drying chamber configured to dry a substrate, which has passed through the wet chamber, by using a supercritical fluid; and
a substrate cleaning chamber configured to supply a cleaning solution to a substrate which has passed through the drying chamber,
wherein the substrate cleaning chamber comprises:
a cleaning chamber housing;
an upper cleaning nozzle configured to supply the cleaning solution toward a top surface of a substrate disposed in the cleaning chamber housing; and
a lower cleaning nozzle configured to supply the cleaning solution toward a bottom surface of a substrate disposed in the cleaning chamber housing.

16. The substrate processing system of claim 15, wherein the substrate cleaning chamber further comprises: a plurality of support pins located in the cleaning chamber housing and configured to support a substrate, and
wherein the support pins are arranged in a circumferential direction.

17. The substrate processing system of claim 15, further comprising:
a first transfer unit configured to transfer a substrate from the wet chamber into the drying chamber; and
a second transfer unit configured to transfer a substrate from the substrate cleaning chamber.

18. The substrate processing system of claim 15, wherein the drying chamber comprises:
a drying chamber housing providing a drying space; and
a drying chuck disposed in the drying chamber housing.

19. The substrate processing system of claim 18, further comprising:
a supercritical fluid supply unit connected to the drying chamber housing to supply the supercritical fluid into the drying space,
wherein the supercritical fluid supply unit comprises: a condenser, a pump, and a heater.

20. The substrate processing system of claim 15, further comprising:
a cleaning solution supply unit connected to the upper cleaning nozzle and to the lower cleaning nozzle to supply the cleaning solution,
wherein the cleaning solution supply unit is configured to supply PGMEA and acetic acid.

21-25. (canceled)
